(19) United States
(12) Patent Application Publication
(10) Pub. No.: US 2008/0180917 A1
(43) Pub. Date: Jul. 31, 2008

(54) CABLE MANAGEMENT SYSTEM AND METHOD OF USE THEREOF

(76) Inventor: Jonathan Gordon Lawrence, Sandy Hook, CT (US)

Correspondence Address: HANLEY, FLIGHT & ZIMMERMAN, LLC, 150 S. WACKER DRIVE, SUITE 2100, CHICAGO, IL, 60606, US

(21) Appl. No.: 11/668,969

(22) Filed: Jan. 30, 2007

(51) Int. Cl. H05K 5/02

(52) U.S. Cl. 361/724

(57) ABSTRACT

Cable management systems and methods of use thereof with an electronic system having modules arranged in a rack system of a cabinet both above and below an air filter location, provides for unobstructed substantially horizontal removal and/or insertion of the air filter into the air filter location. In addition, these cable management systems and methods allow for the unobstructed substantially horizontal insertion and removal of electronic modules during maintenance without interference of adjacent in-service modules and their associated cabling.

### FIELD OF THE DISCLOSURE

This disclosure relates generally to electronic systems, and, more particularly, to cable management systems and methods of use thereof with electronic modules arranged in a rack system of a cabinet both above and below an air filter location.

### BACKGROUND

Electronic systems often mount several modules in close proximity to each other for ease of connecting cables therebetween. Systems have been developed for mounting multiple modules in a single cabinet. Often the cabinet is equipped with a rack system for mounting the modules in vertically stacked association with each other. The modules may be referred to as rack mounted units (RMUs), and several may be mounted and variously interconnected within a cabinet, such as in the case of a router.

Given the undesirable heat that can be generated by the electronic equipment within such a cabinet, these electronic systems typically utilize a cooling system that includes at least a fan to circulate air past the electronic components. To control the airborne dirt or contaminants that would otherwise be stirred in the air and circulated throughout the cabinet, the cooling fan usually is associated with an air filter that is located within the air flow path generated by the fan. Periodic cleaning or replacement of the air filter is indicated to achieve proper cooling, as well as the proper care and maintenance of the electronic system.

Some electronic systems have an air filter located within a plenum that is positioned within a rack system of a cabinet, where the air filter requires substantially horizontal insertion or withdrawal from the plenum. In this manner, RMUs may be mounted above and/or below the cooling and air filter components within a rack. However, this has led to installations having such components installed in a rack of a cabinet wherein the cables are routed to pass through the intended path of insertion or removal of the air filter. Thus, when servicing of the air filter is required, the cables temporarily must be forced toward the side panels of the cabinet, stressing their connections to the modules and potentially causing temporary or permanent critical service and/or communication interruption. This intermittent disruption of the cables and introduction of force to push them toward the cabinet side panels potentially may damage the cables, connectors, and/or modules.

The cabinets used for such electronic systems also often have space for expansion by way of supporting additional modules at lower positions within the rack. However, access to mounting or removal of such additional RMUs is similarly obstructed by the downward extending cables connected to the modules supported above the air filter location. Thus, if attempting to install additional lower modules, the cables from the upper modules need to be forced toward the side panels of the cabinet to permit accessibility. This again introduces potentially damaging temporary movement of the cables.

In addition, the individual cables connected to the upper modules in the aforementioned systems are arranged and bound together in a ribbon format. Thus, the cables are stacked in a single plane, with each successive cable atop the next closest cable. However, when the cables are bent, all within the same plane, each cable is subjected to a different bend radius. For instance, when the cables from the upper modules are bent downward sharply enough to permit the outermost cable to avoid interfering with the access opening so as to permit the removable access panel to be installed, the innermost cable(s) are subjected to ever tighter bends, and may be bent so severely that they potentially exceed their acceptable minimum bend radius. This further compounds the likelihood of potential damage to the integrity of the electronic system. To try to accommodate broader or larger radius bends for the innermost cables, manufacturers alternatively must use cabinets having a fairly substantial depth. But, larger cabinets are more expensive and consume more volume and floor space, which is undesirable and may not be practical in some installations.

### BRIEF DESCRIPTION OF THE DRAWINGS

FIG. 1 is a front perspective view of an example cable routing system constructed in accordance with the teachings of the invention within a cabinet.

FIG. 2 is a closer perspective view of the routing of the cables from the upper modules within the example system shown in FIG. 1.

FIG. 3 is a closer perspective view of the routing of the cables from the upper modules as they extend rearward within the example system shown in FIG. 1.

FIG. 4 is a closer perspective view of the routing of the cables from the rear of the lower modules within the example system shown in FIG. 1.

### DETAILED DESCRIPTION

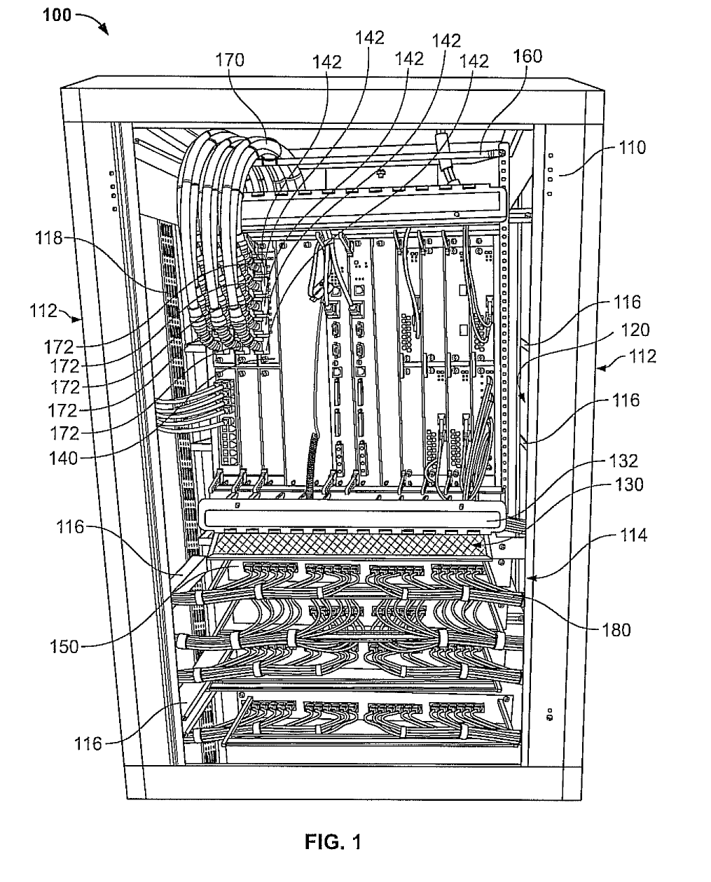

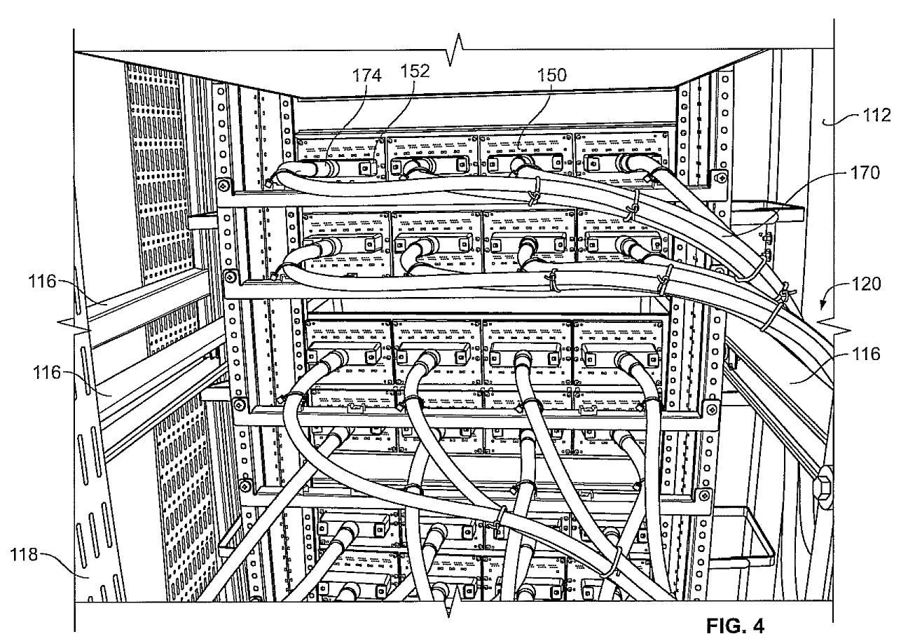

In FIGS. 1-4, an example cable management system 100 for use with cabinet mounted electronic systems is shown. FIG. 1 provides a perspective view of management system 100 being used in a cabinet 110 having side panels 112 and an access opening 114 that receives an access panel (not shown). The cabinet 110 houses a rack system 116 along inner side members 118, and a passageway 120 is formed between each cabinet side panel 112 and the rack 116. A removable air filter 130 is supported at an air filter location and within a housing 132 in the rack 116. The rack 116 also supports upper modules 140 above the air filter 130 and lower modules 150 below the air filter 130. A cable support bar 160 is secured in the cabinet 110 above the upper modules 140.

Within the cable management system 100 disclosed in this example, a series of cables 170 having first connectors 172 is connected to the front of each upper module 140 at module connection ports or connectors 142. As seen in FIGS. 1-3, cables 170 extend from the front of the upper modules 140 toward the access opening 114 and bend upward and over the support bar 160. To avoid extreme bend radius conditions, and thereby reduce stresses in the cables 170, rather than stacking the cables in a planar ribbon formation and bending them within the plane of the ribbon, the cables from each respective upper module 140 are bundled together in an arrangement whereby each cable 170 is in contact with at least two other cables 170. As seen in FIGS. 1-3, this is accomplished in a five cable grouping, for example, by stacking a single cable atop a first pair of cables that in turn is stacked directly atop a second pair of cables, and then securing the cables within the bundle with a flexible fastener, such as a cable tie, twine or the like. The bundle of cables 170 then passes over cable support bar 160, and, to limit incidental movement of the cables 170, they may similarly be secured to the cable support bar 160.

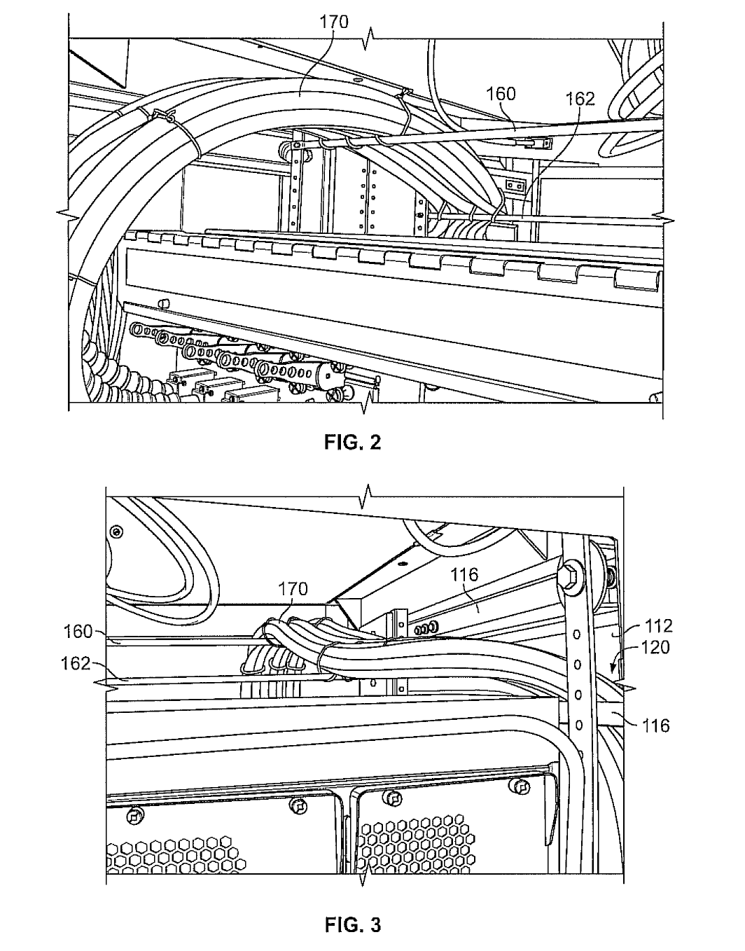

In the example shown in FIGS. 1-3, the cables 170 from an upper module 140 are supported by an additional cable support bar 162 secured in the cabinet 110. Additional cable support bar 162 helps to provide more uniform support for the cables 170. As best seen in FIGS. 2 and 3, as cables 170 pass over the cable support bars 160, 162, the cables 170 continue to be routed rearward and then are routed toward a side panel 112 and downward into a passageway 120 between the rack 116 and the side panel 112. From this position, the cables 170 are conveniently routed downward for connection to other components, which in this example is to the rear of the lower modules 150.

As best seen in FIGS. 1-4, the cable management system 100 of the illustrated example has the series of cables 170 having second connectors 174 that are connected to the rear of each lower module 150 at module connection ports or connectors 152. The cables 170 extend from the rear of the lower modules 150 toward a rear cabinet access opening and bend toward a side panel 112. The cables 170 then bend toward and into a passageway 120 between the rack 116 and the side panel 112. As shown, the cables 170 may bend or loop downward to accommodate excess cable slack before being routed upward to pass over the cable support bars 160, 162. It will be appreciated that the cables 170 for the upper modules 140 alternatively may be conveniently routed downward for connection to other components in the electronic system.

As shown, the cables 170 that are connected to the rear of the lower modules 150 also are bundled in arrangements to avoid extreme bend radius conditions. In this illustrated example, four of the five cables 170 are grouped for connection to the uppermost lower module 150. These four cables 170 are bundled together such that each cable 170 is in contact with at least two other cables 170. This is accomplished by stacking two pairs of cables 170. The four cables 170 may be secured within a bundle such as by using a flexible fastener. In this example, the fifth cable 170 is routed to another lower module 150. Certainly, other arrangements of cable groupings, whether from upper modules 140 or lower modules 150 may be employed.

It will be appreciated that the air filter has an unobstructed path when being inserted or removed in a substantially horizontal position with the cables 170 routed from a first end at the first connectors 172, over the top of the upper modules 140, and then into a side passageway 120, and routed from a second end at the second connectors 174 outward toward a side panel 112, and then into a side passageway 120. Similarly, as best seen in FIG. 1, additional cables 180 may be connected to and extend from the front of the lower modules 150. The cables 180 also are routed to a side passageway 120, between the rack 116 and a side panel 112, for further routing and connection to other components. In this way, the electronic system may be expanded by adding further modules below lower modules 150, because neither the cables 170 from the front of the upper modules 140 nor the cables 180 from the front of the lower modules 150 obstruct access to the rack 116 in the lower region of the cabinet 110.

Given the close proximity of each module within the equipment shelf and their associated cabling, care must be taken to avoid blocking unimpeded access to each module during maintenance, removal and replacement of defective electronic components. Ideally, each individual module should be so cabled as to allow removal without disturbing adjacent in-service units and their cabling. Forming the cables in a manner not substantially in the same plane as the module introduces the potential for service interruption in the neighboring in-service modules.

While for simplicity the present disclosure is made with respect to components within a router system, such as the Alcatel 7750 Router, persons of ordinary skill in the art will readily recognize that the apparatus and methods disclosed herein also may be used in a variety of other electronic systems. Moreover, while the present disclosure shows a particular type and vertical orientation of the upper modules 140 and a particular type and horizontal orientation of the lower modules 150, such systems are merely illustrative and should not be considered as limiting. Accordingly, persons of ordinary skill in the art will readily appreciate that the above described examples are not the only way to implement cable management systems in accordance with the teachings of this disclosure.

In short, although certain example methods, apparatus and articles of manufacture have been described herein, the scope of coverage of this patent is not limited thereto. On the contrary, this patent covers all methods, apparatus and articles of manufacture fairly falling within the scope of the appended claims either literally or under the doctrine of equivalents.

What is claimed is:

1. A cable management system comprising:
a cabinet having an access opening, a rack dimensioned to receive a plurality of modules, and a side passageway disposed between the rack and a side panel of the cabinet;
an air filter support in the rack;
a first module support in the rack above the air filter location and a second module support in the rack below the air filter location;
a plurality of cables connected to a first module located in the first module support; and wherein the cables do not obstruct substantially horizontal removal or insertion of an air filter at the air filter support.

2. A cable management system as defined in claim 1, wherein the first module is an electronic modules having cable connection ports.

3. A cable management system as defined in claim 1, wherein the plurality of cables is secured in a bundle.

4. A cable management system as defined in claim 3, wherein each cable within the bundle is in contact with at least two other cables.

5. A cable management system as defined in claim 1, further comprising a second plurality of cables connected to a second module located in the second module support.

6. A cable management system as defined in claim 5, wherein the second plurality of cables is secured in a bundle and each cable within the bundle is in contact with at least two other cables.

7. A cable management system as defined in claim 1, further comprising a cable support bar secured in the cabinet above the first module.

8. A cable management system as defined in claim 7, wherein the first plurality of cables is secured to the cable support bar.

9. A cable management system as defined in claim 1, wherein the access opening is a front access opening and further comprising a rear access opening.

10. A cable management system as defined in claim 1, wherein the side passageway is a first side passageway and further comprising a second side passageway between the rack and a second side panel of the cabinet.

11. A cable management system as defined in claim 1, wherein a plurality of modules are supported above the air filter support.

12. A cable management system as defined in claim 1, wherein a plurality of modules are supported below the air filter support.

13. A method of routing a plurality of cables within a cabinet having side panels and an access opening, the cabinet containing a rack dimensioned to receive a plurality of modules and to receive an air filter at an air filter location, and defining a side passageway disposed between the rack and a side panel, the method comprising:
supporting a first module in the rack above the air filter location;
supporting a second module in the rack below the air filter location;
routing a first plurality of cables connected to the first module upward, wherein the cables do not obstruct substantially horizontal access to the air filter location.

14. A method as defined in claim 13, further comprising securing a cable support bar above the first module.

15. A method as defined in claim 13, wherein routing the first plurality of cables further comprises bending the first plurality of cables toward the access opening before routing the first plurality of cables upward over a cable support bar.

16. A method as defined in claim 13, wherein routing the first plurality of cables further comprises securing the first plurality of cables into a bundle.

17. A method as defined in claim 16, wherein securing the first plurality of cables into a bundle further comprises arranging the cables such that each cable within the bundle is in contact with at least two other cables within the bundle.

18. A method as defined in claim 13, further comprising sliding horizontally an air filter into the air filter location.

19. A method as defined in claim 13, wherein the cables do not pass between the air filter location and the access opening when an air filter and an access panel are installed.

20. A method as defined in claim 13, further comprising routing a second plurality of cables connected to the second module toward the side panel and into the side passageway.

21. A method as defined in claim 20, wherein routing the second plurality of cables further comprises securing the second plurality of cables into a bundle.

22. A method as defined in claim 21, wherein securing the second plurality of cables into a bundle further comprises arranging the cables such that each cable within the bundle is in contact with at least two other cables within the bundle.
